(19) United States
(12) Patent Application Publication
(10) Pub. No.: US 2007/0247495 A1
(43) Pub. Date: Oct. 25, 2007

(54) Continuous injet printers

(75) Inventors: Philip Geoffrey Spencer, Cambridgeshire (GB); Frank Wilhelm Rohlfing, Cambridgeshire (GB)

Correspondence Address: JOHN P. DE LUCA, 17420 RYEFIELD CT., DICKERSON, MD, 20842, US

(73) Assignee: DOMINO PRINTING SCIENCES PLC

(21) Appl. No.: 11/729,293

(22) Filed: Mar. 27, 2007

(30) Foreign Application Priority Data
Apr. 20, 2006 (EP) 06112802.1

(51) Int. Cl. B41J 2/085; G11C 11/34; H01L 21/8232

(52) U.S. Cl. 347/76; 365/174; 438/142; 257/E21.615

(57) ABSTRACT

The invention provides a method of forming a charge electrode array for a binary continuous inkjet printer, the method including forming the charge electrodes and the driver circuitry for the charge electrodes using common process steps. The process steps are preferably those associated with polycrystalline silicon thin-film transistor technology.

The invention further provides a charge electrode array for a binary continuous inkjet printer when formed according to the inventive method. Such an array may not only be formed integrally with the driver electronics, but also with a phase detector, a deflector, and a velocity detector.

### FIELD OF THE INVENTION

This invention relates to a continuous inkjet (CIJ) printer and, in particular, to a binary continuous inkjet printer.

### BACKGROUND TO THE INVENTION

As is well known, CIJ printing involves the formation of electrically charged drops from a jet of ink, and the subsequent deflection of the charged drops by an electric field to produce an image on a print medium. Electrically conducting ink is forced through a nozzle or through an array of nozzles. As a result of surface tension, the ink jets break up into drops. In a CIJ print head, a controlled sequence of drops, each with identical drop volume, and with constant separation between adjacent drops, can be formed by modulating the jet or the array of jets in a controlled fashion. This can be achieved by modulating the ink pressure in a sinusoidal way at fixed frequency and amplitude, or by modulating the ink velocity relative to the nozzle.

A range of options and techniques to induce pressure modulation, velocity modulation or a combination of both, so that uniform drop sequences are obtained, are known to those skilled in the art. The most widespread of these known techniques is ultra sonic agitation with piezo-electric crystals, converting electrical energy into mechanical energy.

Charge is induced on individual ink drops through capacitive coupling with an electrode; or an array of electrodes if more than one jet is used. Desired levels of charge are induced on drops by applying a voltage to the electrodes at the time the drop separates from the jet. Modulating the voltages at the same frequency as the jet guarantees that the correct level of charge is present on the drops. After charging, the ink drops travel through a constant electric field whose field lines are perpendicular to the jet. Charged drops are deflected by an amount that scales with the charge on the drops.

The technique described here allows printing an image on a medium consisting of a raster of drops.

For commercial applications, CIJ printers with one nozzle, or a linear array of identical nozzles with a fixed pitch, are used. In both cases, the deflection field is kept constant. In single-nozzle printers, a range of voltages is used to achieve different degrees of drop charge, resulting in different degrees of deflection. Uncharged drops are not deflected and fall into a vacuum re-flow, often referred to as a gutter, for re-use. In a multi-nozzle printer, uncharged drops are used for printing and deflected drops are charged with a fixed voltage so that they are deflected into a gutter for ink re-flow and re-use.

Commercial printers of the type to which the present invention applies typically have 100 to 500 jets and associated charge electrodes, arranged in a single line, with a pitch between adjacent electrodes of 100-200 μm, and an electrode length in the order of 1 mm. The electrodes are connected to driver electronics that apply a voltage to the electrodes, and thus induce the desired charge on selected ink drops, at the right time.

The driver electronics are accommodated in integrated circuits (ICs) based on crystalline silicon technology. In conventional commercial printers, driver ICs are connected to the charge electrodes via a flexible conductor foil, with a typical length of 20 cm. There are various technical issues with this arrangement, such as:
1. A printer with 100 to 500 nozzles requires an equal number of connections between charge electrodes and driver electronics, and this reduces the robustness of the print head. This is because the connections between electrodes and electronics are fragile, more so for a small nozzle pitch. In a typical print head, the electrode array connects to a conducting foil which, in turn, connects to at least one pin connector array. The connector array, in turn, plugs into corresponding connector arrays mounted on a printed circuit board. Conducting traces on the circuit board then lead to the driver ICs.
2. The circuit board that accommodates the driver IC must be well separated form the fluid section of the print head, to protect the circuit board and the IC from the corrosive and conducting ink. To achieve this, a foil is required with a typical length of around 20 cm.
3. The foil and its connections to the charge electrodes must withstand inks based on a range of solvents such as acetone, ethanol, methyl-ethyl-ketone and water.
4. The length of foil represents a large capacitive load, which exceeds the capacitive load of the actual charge electrode array, typically by a factor of 200 (1 mm long electrodes and 20 cm long foil). Modulating this capacitive load at a high frequency (50-100 kHz), and a high voltage (50-150V), requires an IC with a low output impedance, which is expensive. ICs of this type represent a small, specialist niche market and are becoming increasing difficult, and expensive, to source.
5. Modulating a long foil at high frequency and high voltage transmits significant radio frequency energy, which may cause interference with radio communications.
6. The foil connection presents constraints on pitch reduction to improve print resolution. A smaller pitch increases the capacitive load even further. It also reduces the robustness of the connection between foil and charge electrode.
7. The fine-pitch conducting foil is also prone to damage from repeated flexure and rough handling.

It is an object of this invention to provide a binary CIJ, and/or one or more components for such a CIJ, which will go at least some way in addressing the aforementioned issues; or which will at least provide a novel and useful choice.

### SUMMARY OF THE INVENTION

Accordingly, in one aspect, the invention provides a method of forming, for a binary continuous inkjet printer, a charge electrode array having N charge electrodes and driver electronics associated with each of said charge electrodes, said method being characterised in that said charge electrodes and at least part of the driver electronics are formed in the same process steps.

Preferably said charge electrodes are formed together with one or more of transistors, diodes, resistors, capacitors and conducting traces.

Preferably said method involves the use of poly-crystalline thin-film transistor techniques.

Preferably said charge electrodes and said driver electronics are formed on a base substrate of glass, quartz, ceramics (alumina or zirconia) or plastics.

Preferably said base layer has deposited thereon a capping of silicon nitride followed by silicon oxide.

Preferably amorphous silicon is deposited on said capping layer in which transistor channels, field-relief regions and source/drain regions are subsequently defined.

Preferably said source/drain regions and said field-relief regions are formed through phosphorous and boron implantations.

Preferably said transistor channels, said field-relief regions and source/drain regions are defined by photo-lithography and then subjected to crystallization.

Preferably the crystallization step is effected by a pulsed laser, or through heating.

Preferably gate metal is deposited and subsequently defined in an overlapping relationship to said transistor channels and said field-relief regions, but insulated there-from by a gate oxide layer.

Preferably the configuration of said gate metal is defined by photo-lithography.

Preferably said method further includes forming one or more of a phase detector, a deflector and a velocity detector using the same process steps.

In a second aspect the invention provides a charge electrode array for a continuous inkjet printer when formed according to the method set forth above.

Preferably said array is fabricated to include an embedded system with serial print data input.

Preferably said driver electronics include a shift register configured to receive N data points; a latch circuit and one or more buffers.

Preferably said driver electronics further include a plurality of NAND gates operable to release data held by said latches.

Preferably said shift register includes two clocked inverters.

Preferably each of said clocked inverters includes a feedback loop consisting of an inverter and another clocked inverter.

In a third aspect the invention provides a binary continuous inkjet printer including the charge electrode array as set forth above.

Many variations in the way the present invention can be performed will present themselves to those skilled in the art. The description which follows is intended as an illustration only of one means of performing the invention and the lack of description of variants or equivalents should not be regarded as limiting. Wherever possible, a description of a specific element should be deemed to include any and all equivalents thereof whether in existence now or in the future.

### BRIEF DESCRIPTION OF THE DRAWINGS

The various aspects of the invention, in one preferred form, will now be described with reference to the accompanying drawings in which:

FIG. 1: shows a section through a typical co-planar charge electrode array and inkjets;

FIG. 2: shows a section through a poly-silicon thin-film transistor formed according to the invention;

FIG. 3: shows a schematic driver circuit for incorporation in a charge electrode array according to the invention;

FIG. 4: shows one form of shift register suitable for use in the driver circuit shown in FIG. 3; and

FIG. 5: shows a charge electrode array in accordance with the invention with integrated phase detector, deflector and velocity detector.

### DETAILED DESCRIPTION OF WORKING EMBODIMENT

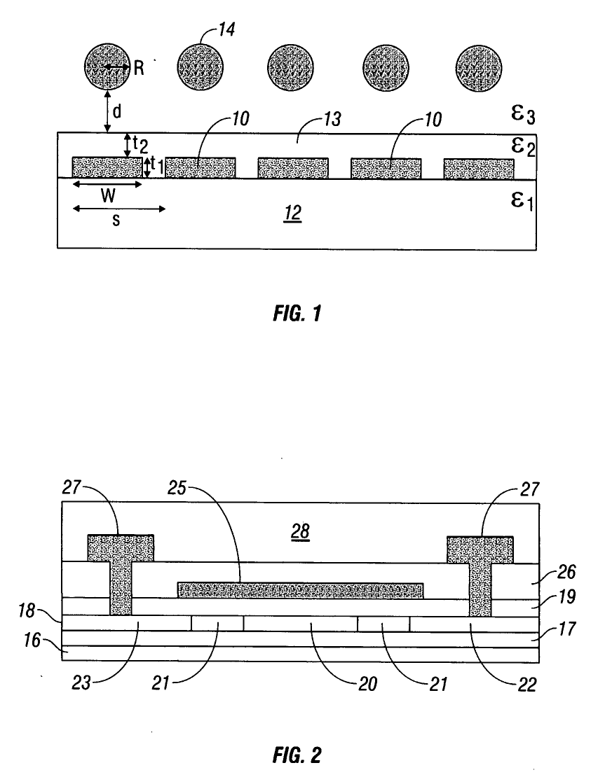

Referring firstly to FIG. 1, a cross section is shown of a general coplanar charge-electrode-array architecture including jets, as typically found in a multi-nozzle printer. Metal electrodes 10 with a pitch s, width Wand thickness t₁ are deposited onto a substrate 12 with a relative permittivity ε₁. This is followed by the deposition of an encapsulation layer 13 with a thickness t₂ and a relative permittivity ε₂. The separation between jets 14 (of radius R) and their electrodes is d, measured from the top of the encapsulation layer 13. However, within the scope of this invention are embodiments that do not require an encapsulation layer 13, in which case the separation d is measured from the top surfaces of the charge electrodes 10. It also falls to be noted, at this stage that forms of printer exist in which annular charge electrodes are provided such that each metal electrode fully or partly surrounds the jet. The advantage of such a design is that the capacitive coupling is more effective, producing the same level of charge as coplanar electrodes at a reduced voltage.

As stated above, commercial printers typically have 100 to 500 jets and electrodes, arranged in a single line with a pitch s of 100-200 cm and an electrode length W in the order of 1 mm.

According to the present invention an integrated charge electrode array is provided in which electrodes and driver electronics are fabricated on the same substrate simultaneously with identical process steps to produce an embedded system with serial print data input. The integrated charge electrode array is preferably fabricated using poly-crystalline silicon thin-film transistor technology. This technology involves the deposition of amorphous silicon (a-Si) onto a substrate using chemical vapour deposition (CVD), and subsequent crystallisation of the a-Si through heating or with short laser pulses, to produce poly-crystalline silicon (p-Si) for transistors fabrication. Gate oxides are then grown or deposited followed by the deposition and photo-lithographic definition of a metal layer to form transistor gates. Contact holes are opened to connect the transistor source and drain with conducting metal traces that are deposited, in the same process as the metal electrodes, to charge the jets.

Turning now to FIG. 2, the poly-Si process of this invention can be understood with reference to this drawing. The charge electrode array and driver circuit (and possibly also the phase detector, velocity detector and the deflector) are deposited on a substrate 16 such as glass, quartz, ceramics (such as alumina or zirconia), plastic or steel foils; or any other material that is compatible with a thin-film p-Si process. A capping layer 17, consisting typically of a silicon nitride layer followed by a silicon oxide layer, each with a thickness of typically several hundred nanometres, is then deposited on top of the substrate via CVD. The presence of the silicon nitride layer prevents impurities from penetrating from the substrate into the poly-Si layer to form the transistor channel. Impurities, in particular sodium, can dramatically degrade the transistor electrical performance and stability.

The back of the substrate may be deposited with the above encapsulation layers, as well, to compensate for the stress that the layers on the front cause.

The following process steps involve the deposition of a-Si layer 18 via CVD and the definition of a-Si geometric structures through photo-lithography. Later in the process these structures provide transistor channels 20, field-relief regions 21, source 22 and drain 23 regions, as well as diodes, resistors, conducting traces and conducting areas for thin-film capacitors. Source/drain and field-relief regions are formed through phosphorus (n-type transistors) and boron (p-type transistors) implantations. Additional low-dose boron implantations for the n-channel and p-channel regions may be necessary to compensate for threshold voltage shifts due to impurities in the channels. Separate implantations to form diodes, resistors, capacitors and conducting traces may be needed if the doses used for source/drain and field-relief regions are not adequate. However, to reduce process costs and to maintain yield, it is advantageous to choose circuit designs in which different active and passive circuit elements share as many implant steps as possible.

After ion implantation, the a-Si features are crystallised with a pulsed laser source or through heating. A range of crystallisation techniques and variants of the above two are known to those skilled in the art, and are deemed to be included within the scope of this invention.

Following crystallisation, an insulating gate oxide layer 19 is deposited via CVD. Depending on the maximum allowable substrate temperature, a thermally grown gate oxide may be used. After gate oxide formation, the gate metal 25 is deposited and defined photo-lithographically. This is followed by the deposition of a capping layer 26, typically consisting of silicon oxide and/or silicon nitride. Contact holes are then opened to the gate metal and to the source/drain regions 22 and 23, either simultaneously, or in separate processes steps. After contact-hole formation, a second metal layer 27 is deposited and defined photo-lithographically to connect to the source/drain regions 22 and 23, to the gate metal layer 25.

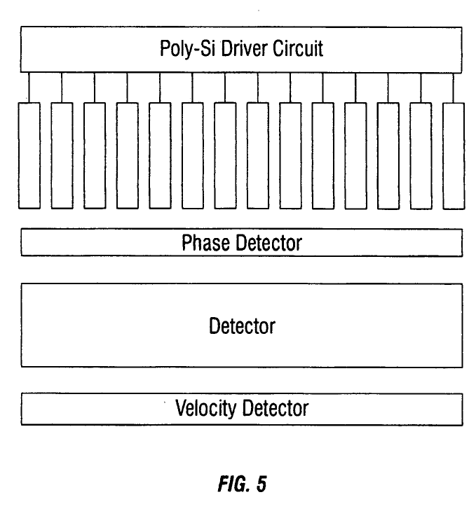

This second metal layer is also used to simultaneously form the charge electrodes. It may also be used for the phase detector, the velocity detector and the deflector in embodiments of the invention, such as is shown in FIG. 5, in which these are integrated on the same substrate as the charge electrode and its driver electronics.

The next process step involves the deposition of an encapsulation layer 28 to protect the conducting traces in the driver circuitry, and the charge electrodes, from the conducting and corrosive ink. For encapsulation, a silicon nitride, a silicon oxide or a combination of both these layers may be deposited via CVD or by sputtering.

In the final process step, contact holes are opened to the top metal for external connections such as power, clocks and data.

The above describes a preferred poly-Si architecture and poly-Si process flow for this invention. One of its key features is that the field-relief regions 21 are overlapped by the gate 25. This architecture is known to be able to operate at a high voltage and to have better electrical stability than architectures in which the field-relief regions are located outside and self-aligned to the gate. This is due to the reduced electric-field strength at the drain, resulting in a low degree of hot-carrier damage. Furthermore, the non-self-aligned poly-Si junctions have broadened doping profiles due to diffusion during the laser crystallisation process. This is known to improve the maximum operating voltage and electrical stability further.

Alternative transistor architectures and poly-Si process flows are known to those skilled in the art, some of these are described briefly below.
1. The use of two or more field-relief regions at the drain and multiple gates to increase transistor operating voltage.
2. Use of the gate as a mask to self-align source/drain regions to the field-relief regions underneath the gate. The source/drain regions may be implanted through the gate oxide for this embodiment.
3. Use of a spacer technology to self-align field-relief regions to the channel and to the source/drain regions. Depending on whether a conducting or non-conducting spacer is used, the field-relief regions will either be outside and aligned to the gate or overlapped by the gate.
4. A third metal may be deposited after contact-hole opening to the second metal to provide external contacts and for the formation of the charge electrode.
5. The use of bottom gate transistor architectures.

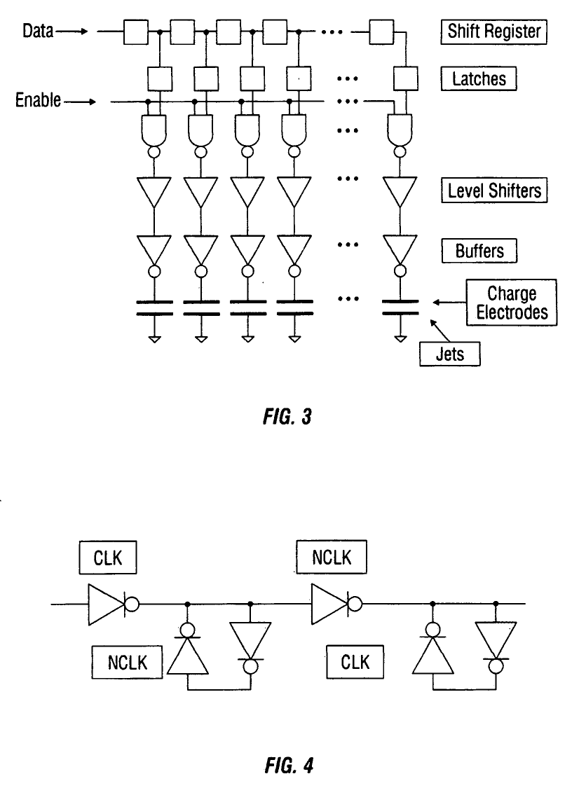

Poly-Si technology can be used to form a variety of circuits of differing architecture. One circuit, devised particularly for application to binary printers, is shown in FIGS. 3 and 4.

FIG. 3 shows a schematic drawing of an electronic driver circuit of a typical embodiment of the invention. Print data consisting of a sequence of N data points (logic 0 or 1) is loaded into a shift register with N stages, whereby N is the number of nozzle jets.

An example of a shift register circuit that is suitable for p-Si technology is shown in FIG. 4. The static logic consists of two clocked inverters CLK and NCLK, each with a feedback loop consisting of an inverter and another clocked inverter. Ideally, the complementary clock NCLK is produced from CLK on the substrate in p-Si technology, either in a single sub-circuit to provide for the whole shift register or in multiple sub-circuits for a single shift register stage or a group of shift register stages.

A common buffer, local buffers or a combination of both are used to drive the required shift register clock load.

The two feedback loops may be omitted, in which case the static logic reduces to dynamic logic. The advantages of this are a lower transistor count per nozzle (reducing from 44 per shift register stage in static logic to 20 in dynamic logic), faster operating frequency, better process yield, less space and reduced processing costs. However, the dynamic logic circuit requires an environment with low parasitic capacitances and may not work at low frequency if the transistor leakage current is high at the maximum operating temperature of the circuit.

Once the shift register is filled with data, the N data points are latched. The circuit in FIG. 4 can be used as a latch circuit. Depending on the timing details of the overall circuit operation, a transparent latch may be used, which reduces the circuit in FIG. 4 to a single clocked inverter with a feedback loop. As for the complementary clock, the complementary latch clock is ideally produced on the substrate in p-Si technology. This reduces the number of external connections to the substrate.

Latched data is combined with an enable signal at N NAND gates, and the outcome is then buffered to charge the electrode array. Level shifters may be introduced between logic and buffers to avoid operating the logic at the same high voltage level as the charge electrode.

The circuits in FIGS. 3 and 4 describe a preferred embodiment of the invention. However, alternative embodiments are possible and will be known to those skilled in the art. By way of example, the data shift register in FIG. 3 must typically be reloaded 4 to 16 times per drop period to generate the correct phase relationship between the signal supplied to the piezo-electric crystals to modulate the jets, and the drop-charging waveform applied to the charge-electrode array. These high data-rates (in the order of 100 MHz) usually preclude the use of a single, long, shift register, and force the adoption of several shorter registers in parallel. Furthermore, it is often required to switch the entire charging circuit between a ground-referenced state for printing, and a reduced-operating voltage state referenced to the normal charge potential. This is to permit phase measurement between prints by test charging drops, whilst ensuring all drops are charged and deflected to the gutter.

Another important embodiment of the invention is shown in FIG. 5, where the phase detector, the velocity detector and the deflector are fabricated on the same substrate simultaneously, with identical process steps, as the charge electrode array and its driver electronics. For this embodiment a non-planar substrate may be chosen so that phase detector, velocity detector and deflector are separated form the jets by a greater distance than the driver electronics and the charge electrode. Note that the area occupied by driver circuitry is much smaller than the charge electrode array area.

This invention overcomes all the technical issues with conventional charge electrode arrays that are listed above. As the print data is presented serially, the number of connections to the substrate reduces from 100-500 to just a few, typically 5-10, and this number is less dependent on the number of jets and electrodes. This greatly improves the robustness of the system. Because of the low number of external connections, a conducting foil is not required, and a wide range of connectors and wires can be used. The separation between these components is not limited by the electrode pitch. The driver electronics and the integrated connections between electronics and charge electrodes are protected from the corrosive and conducting ink through layers of deposited thin film. Depending on the ink used, this can be a layer or a combination of layers that is part of a standard poly-Si process.

The length of the connections between the output stage of the driver electronics and the electrodes reduces from typically 20 cm to a few hundred μm, resulting in a dramatic reduction in capacitive load. Hence, the buffering required to charge the electrodes reduces by a similar factor; as does the transmitted radio frequency energy. Furthermore, with integrated driver electronics there are no constraints in electrode pitch as far as the connections between electrodes and driver electronics are concerned, enabling higher-resolution printing.

Finally, with p-Si technology, the driver electronics can be optimised for a specific charge electrode design. In conventional charge electrodes, there is always a mismatch between charge electrode and drive circuit designs as the commercial ICs available are not produced specifically for application to charge electrodes.

1. A method of forming, for a binary continuous Inkjet printer, a charge electrode array having N charge electrodes and driver electronics associated with each of said charge electrodes, said method being characterised in that said charge electrodes and at least part of the driver electronics are formed in the same process steps.

2. A method as claimed in claim 1 wherein said method comprises forming, along with said charge electrodes, one or more of transistors, diodes, resistors, capacitors and conducting traces.

3. A method as claimed in claim 1 wherein said method involves the use of poly-crystalline silicon thin-film transistor techniques.

4. A method as claimed in claim 3 wherein said charge electrodes and said driver electronics are formed on a base substrate of glass, quartz, ceramics (alumina or zirconia) or plastics.

5. A method as claimed in claim 4 wherein said base layer has deposited thereon a capping of silicon nitride followed by silicon oxide.

6. A method as claimed in claim 5 wherein amorphous silicon is deposited on said capping layer in which transistor channels, field-relief regions and source/drain regions are subsequently defined.

7. A method as claimed in claim 6 wherein said source/drain regions and said field-relief regions are formed through phosphorous and boron implantations.

8. A method as claimed in claim 7 wherein said transistor channels, field-relief regions and source/drain regions are defined by photo lithography and then subjected to crystallization.

9. A method as claimed in claim 8 wherein crystallization is effected by a pulsed laser, or through heating.

10. A method as claimed in claim 6 wherein gate metal is deposited and subsequently defined in an overlapping relationship to said transistor channels and said field-relief regions, but insulated there-from by a gate oxide layer.

11. A method as claimed in claim 10 wherein the configuration of said gate metal is defined by photo-lithography.

12. A method as claimed in claim 1 further including forming one or more of a phase detector, a deflector and a velocity detector using the same process steps.

13. A charge electrode array for a binary continuous inkjet printer when formed according to the method claimed in claim 1.

14. A charge electrode array as claimed in claim 13 including an embedded system with serial print data input.

15. A charge electrode array as claimed in claim 14 wherein said driver electronics include a shift register configured to receive N data points;
a latch circuit and one or more buffers.

16. A charge electrode array as claimed in claim 15 further including a plurality of NAND gates operable to release data held by said latches.

17. A charge electrode array as claimed in claim 16 wherein said shift register includes two clocked inverters.

18. A charge electrode array as claimed in claim 17 wherein each of said clocked inverters includes a feedback loop consisting of an inverter and another clocked inverter.

19. A binary continuous inkjet printer including the charge electrode array as claimed in claim 13.
